(19) United States
(12) Patent Application Publication
(10) Pub. No.: US 2008/0297179 A1
(43) Pub. Date: Dec. 4, 2008

(54) MULTILAYER MANUFACTURING FOR CONDUCTIVITY SENSOR

(76) Inventors: Chang-Dong Feng, Long Beach, CA (US); Fong Shyr Yang, Tustin, CA (US)

Correspondence Address: WESTMAN CHAMPLIN & KELLY, P.A., SUITE 1400, 900 SECOND AVENUE SOUTH, MINNEAPOLIS, MN, 55402-3244, US

(21) Appl. No.: 12/128,081

(22) Filed: May 28, 2008

Related U.S. Application Data
(60) Provisional application No. 60/932,069, filed on May 29, 2007.

(51) Int. Cl. G01R 27/02

(52) U.S. Cl. 324/693

(57) ABSTRACT

A contacting-type conductivity sensor is provided. A first insulating layer has a proximal surface to contact a liquid sample, and an opposite, distal surface. A plurality of electrodes is disposed on the proximal surface of the first insulating layer. Each of a plurality of conductive vias is electrically coupled to a respective one of the plurality of electrodes, where each via defines a conductive path from the proximal surface to the distal surface of the first insulating layer. A plurality of traces is disposed adjacent the distal surface of the first insulating layer, and each of the plurality of traces is electrically coupled to a respective one of the plurality of conductive vias. A plurality of conductors is provided where each conductor is electrically coupled to a respective one of the plurality of traces. A cover layer is coupled to the first insulating layer.

### CROSS-REFERENCE TO RELATED APPLICATION

The present application is based on and claims the benefit of U.S. provisional patent application Ser. No. 60/932,069, filed May 29, 2007, the content of which is hereby incorporated by reference in its entirety.

### BACKGROUND

Conductivity measurement sensors are well known in the art and are used to measure the conductivity of a fluid, such as a liquid or a dispersion of solids suspended in a liquid. Conductivity sensors are often used to investigate the properties of electrolytes in solution, such as the degree of dissociation, the formation of chemical complexes, and the hydrolysis. The conductivity of a fluid may also be used to measure a wide variety of other parameters, such as the amount of contaminants in drinking water and a measure of chemical concentrations in industrial processes. Applications such as these involve the determination of conductivities in many physical environments.

The units of conductivity are Siemens/cm, which are identical to the older unit of mhos/cm. Conductivity measurements cover a wide range of solution conductivity from pure water at less than 1×10⁻⁷ S/cm to values in excess of 1 S/cm for concentrated solutions.

One conductivity measurement technique includes contacting a solution with electrically conducting electrodes. For example, one contacting conductivity measurement technique employs a sensor with two metal or graphite electrodes in contact with the electrolyte solution. An alternating current (AC) voltage is applied to the electrodes by the conductivity analyzer, and the resulting AC current that flows between the electrodes is used to determine the conductance. Contacting-type conductivity sensors generally employ two, or sometimes four, contacting electrodes, which physically contact the sample solution. In the case of four-electrode contacting sensors, the four-electrodes are exposed to the sample solution and a current is passed through one pair of electrodes. A voltage change between the other pair of electrodes is then measured. Based on the current and voltage, the conductivity of the liquid is calculated. Traditionally, contacting-type conductivity sensors, such as two or four-electrode sensors, are made by inserting conductive rods, (made of stainless steel, titanium, graphite, etc.) in a plastic tube, which rods are then sealed with epoxy along their length. The cross section of one end of the plastic tube is then used to expose the electrodes to the sample solution. FIG. 1A is a diagrammatic view of a four-electrode contacting-type conductivity sensor 10 in accordance with the prior art. Sensor 10 is coupled to a suitable conductivity analyzer 12. End 14 of sensor 10 exposes ends 16 of conductive rods 18 to a sample solution disposed proximate end 14. FIG. 1B is a bottom plan view of sensor 10 illustrating ends 16 of rods 18.

Recently, contacting-type conductivity sensors, such as two and four-electrode conductivity sensors have been made by using semiconductor-like, planar manufacturing technologies. The electrodes are deposited on a passivated silicon wafer through suitable processing techniques, such as thin/thick film technology. Conductivity sensors manufactured in accordance with such semiconductor processing techniques can be mass-produced resulting in reduced size and cost of such sensors. However, the reduction in size of semiconductor-based conductivity sensors creates other manufacturing difficulties. Providing a semiconductor-based contacting-type conductivity sensor design that facilitated low-cost semiconductor-based manufacturing techniques would further benefit the art.

### SUMMARY

In one aspect, a contacting-type conductivity sensor is provided. A first insulating layer has a proximal surface to contact a liquid sample, and an opposite, distal surface. A plurality of electrodes is disposed on the proximal surface of the first insulating layer. Each of a plurality of conductive vias is electrically coupled to a respective one of the plurality of electrodes, where each via defines a conductive path from the proximal surface to the distal surface of the first insulating layer. A plurality of traces is disposed adjacent the distal surface of the first insulating layer, and each of the plurality of traces is electrically coupled to a respective one of the plurality of conductive vias. A plurality of conductors is provided where each conductor is electrically coupled to a respective one of the plurality of traces. A cover layer is coupled to the first insulating layer.

In another aspect, a different contacting-type conductivity sensor is provided. The sensor includes a first insulating layer having an outer surface to contact a liquid sample, and an inner, inter-distal surface. A first pair of electrodes is disposed on the outer surface of the first insulating layer. A plurality of conductive vias is provided where each via is electrically coupled to a respective one of the first pair of electrodes, and each via defines a conductive path therethrough. A plurality of traces is disposed adjacent the inter-distal surface of the first insulating layer, and each of the plurality of traces is electrically coupled to a respective one of the plurality of conductive vias. A plurality of conductors is also provided where each conductor is electrically coupled to a respective one of the plurality of traces. A second insulating layer has an outer surface, and an inner, inter-distal surface coupled to the first insulating layer.

### BRIEF DESCRIPTION OF THE DRAWINGS

FIG. 1A is a diagrammatic view of a four-electrode contacting conductivity sensing system in accordance with the prior art.

FIG. 1B is a bottom plan view of a four-electrode contacting-type conductivity sensor.

FIG. 2A is a bottom plan view of a four-electrode contacting-type conductivity sensor in accordance with an embodiment of the present invention.

FIG. 2B is a perspective view of a first layer of a four-electrode contacting-type conductivity sensor in accordance with an embodiment of the present invention.

FIG. 2C is a perspective view of a four-electrode contacting-type conductivity sensor in accordance with an embodiment of the present invention.

FIG. 3 is a perspective view of a four-electrode contacting-type conductivity sensor in accordance with another embodiment of the present invention.

FIG. 4 is a partial front elevation view of the conductivity sensor shown in FIG. 3.

FIG. 5 is a perspective view of a portion of the contacting-type conductivity sensor shown in FIG. 3.

FIG. 6 is a perspective view of a portion of a contacting-type conductivity sensor in accordance with another embodiment of the present invention.

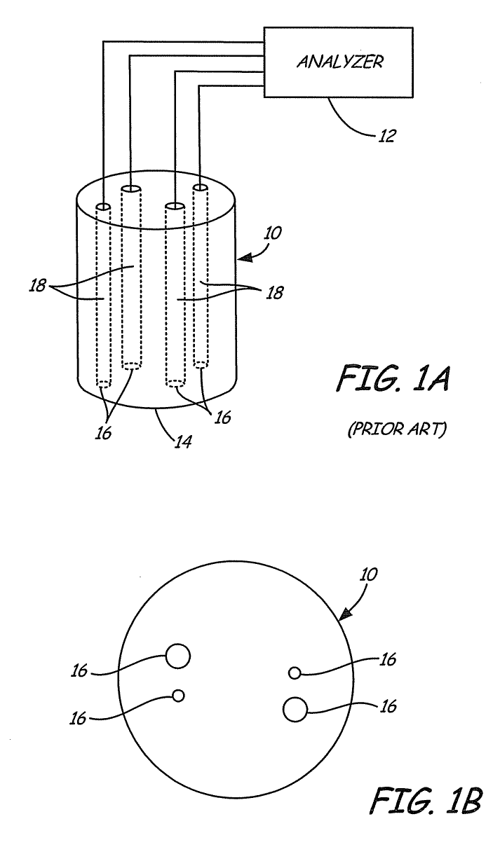

### DETAILED DESCRIPTION

Embodiments of the present invention generally provide a contacting-type conductivity sensor constructed from multiple layers of insulating material, and at least one electrode where a trace is coupled to a conductive via such that the position of the electrical connection to the at least one electrode is not dependent on the position of the contacting portion of the electrode.

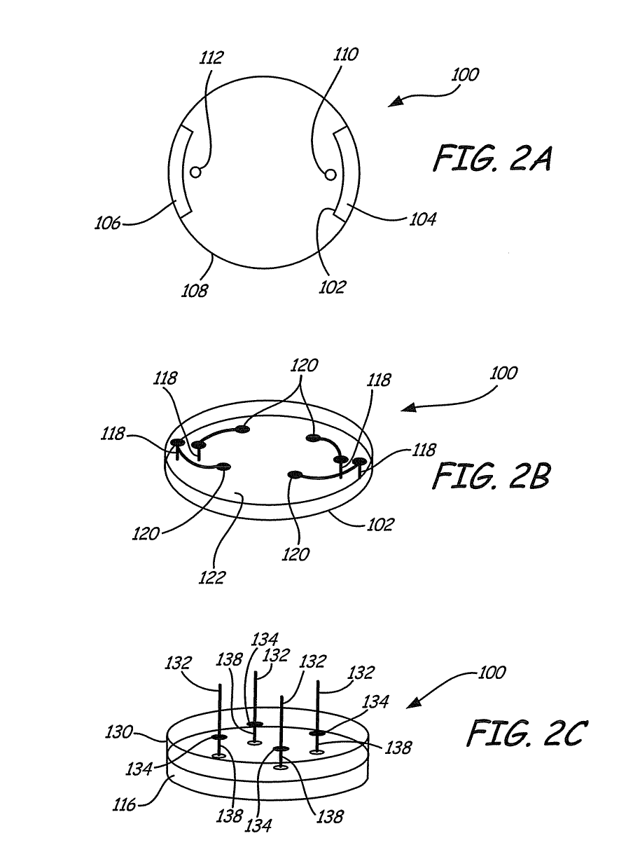

FIG. 2A is a bottom plan view of a four-electrode contacting-type conductivity sensor in accordance with an embodiment of the present invention. FIG. 2A illustrates that sensor 100 is preferably circular, and includes four electrodes that are disposed on the proximal surface 102 (relative to the sample). A pair of arcuate electrodes 104, 106 is disposed proximate circumferential edge 108 of sensor 100. Two additional circular electrodes 110, 112 are disposed inwardly from circumferential edge 108. Maximizing the distance between the driving electrodes improves the linearity of sensor 100. FIG. 2A simply illustrates a preferred design, and certainly other arrangements are contemplated in accordance with embodiments of the present invention.

One of the difficulties in the design of contacting-type conductivity sensors is that the driving electrodes should be located as far apart from one another as possible in order to improve the linearity of the sensor. However, in order to actually electrically couple to an analyzer, it is convenient for the conductors to run close to one another. In order to balance these two design considerations, embodiments of the present invention generally provide multiple layers that are bonded, or otherwise coupled together in order to form a multilayer conductivity sensor.

FIG. 2B is a diagrammatic perspective view of a portion of sensor 100. Proximal surface 102 is located underneath layer 116. Electrodes 104, 106, 110, and 112 are coupled, in any suitable manner, to conductive vias or posts 118. Vias or posts 118 can be constructed in any suitable manner that provides an electrical interconnect from proximal surface 102 to pads 120 disposed on surface 122. For example, vias or posts 118 can be constructed in accordance with techniques disclosed in U.S. Patent Publication Number 2006/0219564 A1, assigned to the same assignee as the present application. Those skilled in the art will appreciate that layer 116 can be constructed as one monolithic layer or it can be built up as a construction of multiple thinner layers depending upon the manufacturing tolerances desired. Further, both the electrode patterns on proximal surface 102, as well as the traces that couple vias 118 to pads 120 can be generated using any suitable thin/thick film processing techniques. Suitable examples of processing techniques include physical vapor deposition (PVD), electrochemical deposition (ECD), molecular beam epitaxy (MBE), atomic layer deposition (ALD), and thick film screen printing. Moreover, electrode material may simply be provided in sheet form and then selectively removed to generate the electrodes and/or traces. Suitable thin/thick film removal processes include etching processes, such as wet etching or dry etching.

FIG. 2C is a diagrammatic perspective view of sensor 100 in accordance with an embodiment of the present invention. Sensor 100 includes layer 116 described with respect to FIG. 2B, as well as layer 130 bonded thereto. Preferably each of layers 116 and 130 is comprised of a substrate constructed from a suitable insulating material organic or inorganic, such as alumina (Al₂O₃) or polymer. Layers 116 and 130 can be bonded together in any suitable manner in accordance with any techniques currently known or later developed. Further, the electrical interconnection between pins or conductors 132 and their respective pads 134 can be effected in accordance with any suitable techniques including soldering, brazing, or welding. Further still, the construction of vias or posts 138 passing through layer 130 can be the same as that of posts or vias 118, described with respect to FIG. 2B. Further still, the electrical interconnection between vias or posts 138 and pads 120 on layer 116 can be done in any suitable manner. Suitable techniques include solder, conductive adhesive, brazing, or any other suitable techniques. It is preferred that the mechanical connection of layer 130 to layer 116 form a hermetic seal between the two layers. However, any mechanical connection that is robust enough to maintain layers 130 and 116 together for a suitably long product lifetime can be used. In fact, layers 130 and 116 could simply be clamped together via a suitable mechanical clamp or mechanical fastener(s).

As illustrated in FIG. 2C, contacting pins 132 on the distal surface of layer 130 can be set away from circumferential edge 108 by way of conductive traces on an inter-distal surface of layer 116 thereby facilitating attachment of wires to pins 132.

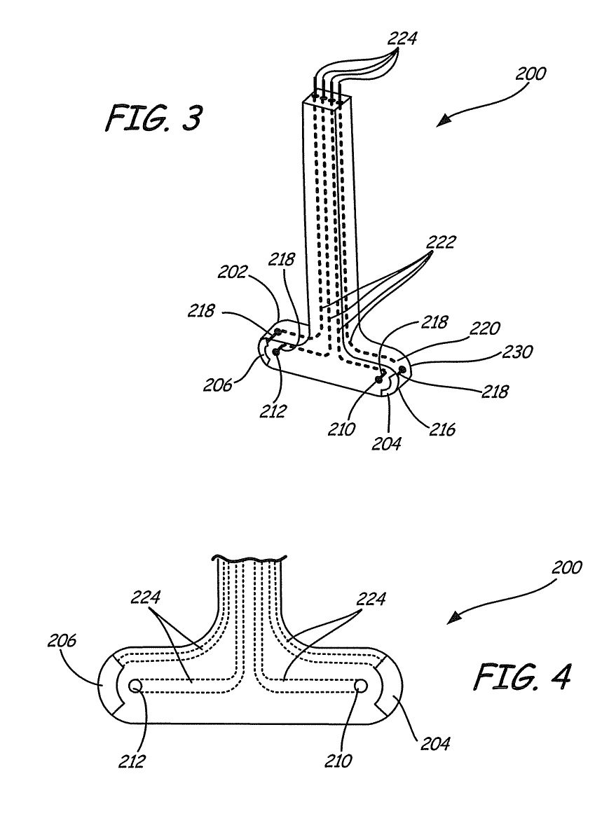

FIG. 3 is a diagrammatic view of multi-conductor contacting-type conductivity sensor in accordance with another embodiment of the present invention. Sensor 200 bears some similarities to sensor 100, and like components are numbered similarly. Sensor 200 includes layer 216 having a first surface 202 upon which electrodes 204, 206, 210, and 212 are located. Conductive vias or posts 218 electrically interconnect first side 202 of layer 216 to an inner side 220 upon which electrical traces 222 are disposed. Traces 222 couple vias 218 to pins 224 that can then be coupled suitable wires or other electrical interconnections. Layer 230 is bonded, or otherwise coupled to layer 216, such as by clamping, or any of the methods described above with respect to FIG. 2C and layers 116 and 130, to preferably seal traces 222 from the liquid sample. While sensor 200 is illustrated as having an approximately inverted ‘T’ shape, any suitable shape can be used.

FIG. 4 is a diagrammatic front elevation view of a portion of sensor 200. FIG. 4 illustrates electrodes 204, 206, 210, and 212 with greater clarity. Further, FIG. 4 illustrates the various conductive traces 224 (illustrated in phantom in FIG. 4) running within sensor 200. The design of sensor 200 allows the driving electrodes to be disposed relatively far apart, while the electrical interconnection of the sensor can be effected using relatively closely-spaced pins or wire (224).

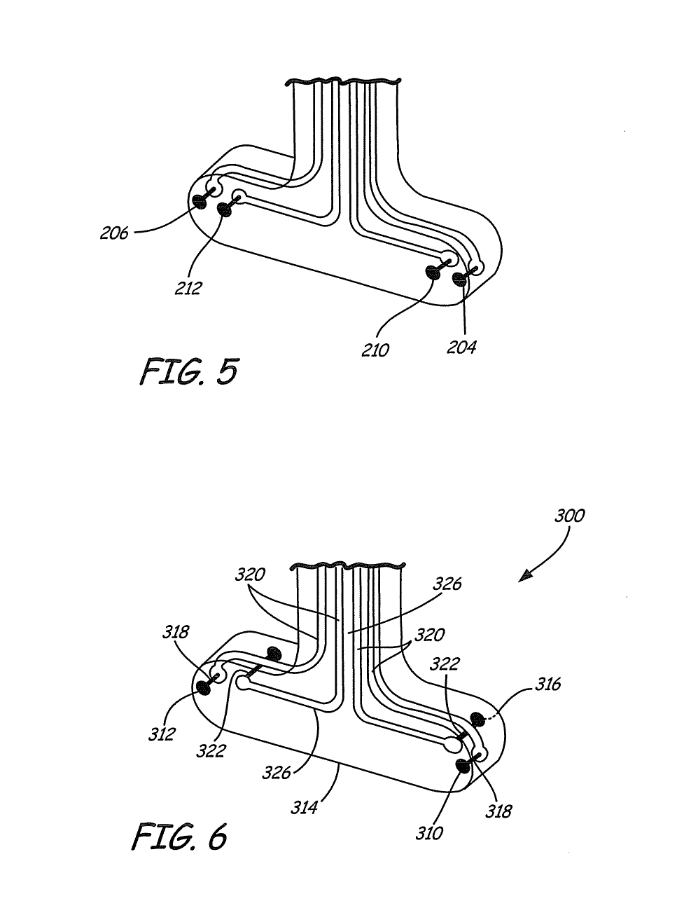

FIG. 5 is a diagrammatic perspective view of a portion of sensor 200 illustrated in FIGS. 3 and 4. FIG. 5 shows the arrangement of all electrodes 204, 206, 210, and 212 being located on the same side. However, that is merely one configuration, and FIG. 6 illustrates an arrangement for a four-electrode contacting type conductivity sensor in accordance with another embodiment of the present invention. Specifically, FIG. 6 illustrates a portion of sensor 300 having circular electrodes 310 and 312 disposed on a first side 314 of sensor 300. Electrodes with shapes similar to electrodes 204 and 206 are then disposed on opposite surface 316 of sensor 300. As can be seen in FIG. 6, vias or posts 318 electrically interconnect electrodes 310 and 312 to internal traces 320. Similarly, vias or posts 322 electrically interconnect traces 326 to electrodes (not shown in FIG. 6) disposed on opposite surface 316.

The sensors shown in FIGS. 3-6 use multi-layer technology to allow the traces themselves to act as an electrical conductor, carrying the signal directly to the sensor connector without the need for additional wires and a housing. It is believed that this further simplifies construction of a four-electrode contacting-type conductivity sensor, thereby reducing costs. As can be appreciated, both surfaces of sensor 300, such as surface 314 and 316 would be in contact with the sample solution. The surface on the inner layer, such as layer 220, supports traces, such as traces 222, 320, or 326 leading to pins or a connector at the top, while the multiple layer bonding would preferably hermetically seal the traces between the ceramic substrates. As described above, electrodes can be located such that they are all on one surface, or some electrodes can be located on opposite surfaces, while maintaining all traces leading to connector pins hermetically sealed within the multiple layers of ceramic, such as alumina.

Although the present invention has been described with reference to preferred embodiments, workers skilled in the art will recognize that changes may be made in form and detail without departing from the spirit and scope of the invention.

What is claimed is:

1. A contacting-type conductivity sensor comprising:
a first insulating layer having a proximal surface to contact a liquid sample, and an opposite, distal surface;
a plurality of electrodes disposed on the proximal surface of the first insulating layer;
a plurality of conductive vias each electrically coupled to a respective one of the plurality of electrodes, each via defining a conductive path from the proximal surface to the distal surface of the first insulating layer;
a plurality of traces disposed adjacent the distal surface of the first insulating layer, each of the plurality of traces being electrically coupled to a respective one of the plurality of conductive vias;
a plurality of conductors, each being electrically coupled to a respective one of the plurality of traces; and
a cover layer coupled to the first insulating layer.

2. The conductivity sensor of claim 1, wherein the cover layer is constructed from a second insulating layer.

3. The conductivity sensor of claim 2, wherein the first and second insulating layers are bonded together.

4. The conductivity sensor of claim 3, wherein the first and second insulating layers form a hermetic seal together.

5. The conductivity sensor of claim 1, wherein the first insulating layer is formed of an inorganic material.

6. The conductivity sensor of claim 5, wherein the inorganic material is alumina.

7. The conductivity sensor of claim 1, wherein the first insulating layer is formed of an organic material.

8. The conductivity sensor of claim 7, wherein the organic material is a polymer.

9. The conductivity sensor of claim 1, wherein at least one of the vias comprises a solid post of conductive material.

10. The conductivity sensor of claim 1, wherein the first insulating layer is round and has a circumferential edge, and a pair of the plurality of electrodes are disposed adjacent the circumferential edge.

11. The conductivity sensor of claim 1, wherein the first insulating layer is constructed from a plurality of thinner layers.

12. A contacting-type conductivity sensor comprising:
a first insulating layer having an outer surface to contact a liquid sample, and an inner, inter-distal surface;
a first pair of electrodes disposed on the outer surface of the first insulating layer;
a plurality of conductive vias each electrically coupled to a respective one of the first pair of electrodes, each via defining a conductive path therethrough;
a plurality of traces disposed adjacent the inter-distal surface of the first insulating layer, each of the plurality of traces being electrically coupled to a respective one of the plurality of conductive vias;
a plurality of conductors, each being electrically coupled to a respective one of the plurality of traces; and
a second insulating layer having an outer surface, and an inner, inter-distal surface coupled to the first insulating layer.

13. The conductivity sensor of claim 12, and further comprising:
a second pair of electrodes disposed on the outer surface of the second insulating layer; and
wherein the plurality of conductive vias includes conductive vias coupled to a respective one of the second pair of electrodes, each via defining a conductive path from the outer surface to the inter-distal surface of the first insulating layer.

14. The conductivity sensor of claim 12, and further comprising:
a second pair of electrodes disposed on the outer surface of the second insulating layer; and
wherein the plurality of conductive vias includes conductive vias coupled to a respective one of each of the second pair of electrodes.

15. The conductivity sensor of claim 12, wherein the first and second insulating layers are bonded together.

16. The conductivity sensor of claim 12, wherein the first and second insulating layers form a hermetic seal together.

17. The conductivity sensor of claim 12, wherein the first insulating layer is formed of inorganic material.

18. The conductivity sensor of claim 17, wherein the inorganic material is alumina.

19. The conductivity sensor of claim 12, wherein the insulating layer is formed of an organic material.

20. The conductivity sensor of claim 19, wherein the organic material is a polymer.

21. The conductivity sensor of claim 12, wherein at least one of the vias comprises a solid post of conductive material.
